(19) United States
(12) Patent Application Publication
(10) Pub. No.: US 2012/0013006 A1
(43) Pub. Date: Jan. 19, 2012

(54) CHIP SCALE PACKAGE AND FABRICATION METHOD THEREOF

(75) Inventors: Chiang-Cheng Chang, Taichung (TW); Chien-Ping Huang, Taichung (TW); Chun-Chi Ke, Taichung (TW)

(73) Assignee: SILICONWARE PRECISION INDUSTRIES CO., LTD., Taichung (TW)

(21) Appl. No.: 12/955,613

(22) Filed: Nov. 29, 2010

(30) Foreign Application Priority Data
Jul. 13, 2010 (TW) 099122934

(51) Int. Cl. H01L 23/485; H01L 21/786

(52) U.S. Cl. 257/738; 438/114; 257/E23.021; 257/E21.702

(57) ABSTRACT

A fabrication method of a chip scale package is provided, which includes forming a protection layer on the active surface of a chip and fixing the inactive surface of the chip to a transparent carrier; performing a molding process; removing the protection layer from the chip and performing a redistribution layer (RDL) process, thereby solving the conventional problems caused by directly attaching the chip on an adhesive film, such as film-softening caused by heat, encapsulant overflow, warpage, chip deviation and contamination that lead to poor electrical connection between the wiring layer formed in the RDL process and the chip electrode pads and even waste product as a result. Further, the transparent carrier employed in the invention can be separated by laser and repetitively used in the process to help reduce the fabrication cost.

### BACKGROUND OF THE INVENTION

1. Field of the Invention

The present invention relates generally to semiconductor packages and fabrication methods thereof, and more particularly, to a chip scale package and a fabrication method thereof.

2. Description of Related Art

A chip scale package (CSP) is characterized in that the package size is equivalent to the size of the chip that is disposed in the package. U.S. Pat. No. 5,892,179, No. 6,103,552, No. 6,287,893, No. 6,350,668 and No. 6,433,427 disclose a conventional CSP structure, wherein a built-up structure is directly formed on a chip without using a chip carrier, such as a substrate or a lead frame, and a redistribution layer (RDL) technique is used to accomplish a redistribution of the electrode pads of the chip to a desired pattern.

However, the application of the RDL technique or disposing of conductive traces on the chip is limited by the size of the chip or the area of the active surface of the chip. Particularly, as chips are developed towards high integration and compact size, they do not have enough surface area for mounting of more solder balls for electrical connection to an external device.

Accordingly, U.S. Pat. No. 6,271,469 provides a fabrication method of a wafer level chip scale package (WLCSP), wherein a built-up layer is formed on the chip of the package so as to provide enough surface area for disposing I/O terminals or solder balls.

Referring to FIG. 1A, an adhesive film 11 is prepared, and a plurality of chips 12, each having an active surface 121 and an opposite inactive surface 122, is provided and attached to the adhesive film 11 via the active surfaces 121 thereof, respectively. Therein, the adhesive film 11 can be such as a heat-sensitive adhesive film. Referring to FIG. 1B, a package molding process is performed to form an encapsulant 13 such as an epoxy resin encapsulating the inactive surfaces 122 and side surfaces of the chips 12. Then, the adhesive film 11 is removed by heating so as to expose the active surfaces 121 of the chips 12. Referring to FIG. 1C, by using an RDL technique, a dielectric layer 14 is formed on the active surfaces 121 of the chips 12 and the surface of the encapsulant 13 and a plurality of openings is formed in the dielectric layer 14 to expose the electrode pads 120 of the chips. Then, a wiring layer 15 is formed on the dielectric layer 14 and electrically connected to the electrode pads 120. A solder mask layer 16 with a plurality of openings is further formed on the wiring layer 15, and solder balls 17 are mounted on the wiring layer 15 in the openings of the solder mask layer 16. Subsequently, a singulation process is performed to obtain a plurality of packages.

In the above-described packages, the surface of the encapsulant encapsulating the chip is larger than the active surface of the chip and therefore allows more solder balls to be mounted thereon for electrically connecting to an external device.

However, since the chip is fixed by being attached to the adhesive film, deviation of the chip can easily occur due to film-softening and extension caused by heat, especially in the package molding process, thus adversely affecting the electrical connection between the electrode pads of the chip and the wring layer during the subsequent RDL process. Further, the use of the adhesive film leads to increase of the fabrication cost.

Referring to FIG. 2, since the adhesive film 11 is softened by heat in the package molding process, overflow 130 of the encapsulant 13 can easily occur to the active surface 121 of the chip 12 and even contaminate the electrode pads 120 of the chip 12, thus resulting in poor electrical connection between the electrode pads of the chip and subsequently formed wiring layer and even causing product failure.

Referring to FIG. 3A, since the adhesive film 11 supports a plurality of chips 12, warpage 110 can easily occur to the adhesive film 11 and the encapsulant 13, especially when the encapsulant 13 has a small thickness. As such, the thickness of the dielectric layer formed on the chip during the RDL process is not uniform. To overcome this drawback, a hard carrier 18 as shown in FIG. 3B is required so as for the encapsulant 13 to be secured thereto through an adhesive 19, which however complicates the process and increases the fabrication cost. Further, when the RDL process is completed and the hard carrier 18 is removed, some adhesive residue 190 may be left on the encapsulant, as shown in FIG. 3C. Related techniques are disclosed in U.S. Pat. No. 6,498,387, No. 6,586,822, No. 7,019,406 and No. 7,238,602.

Therefore, it is imperative to provide a chip scale package and a fabrication method thereof so as to ensure the electrical connection quality between the chip electrode pads and the wiring layer of the package, improve the product reliability and reduce the fabrication cost.

### SUMMARY OF THE INVENTION

In view of the above-described drawbacks, the present invention provides a fabrication method of a chip scale package, which comprises the steps of providing a plurality of chips and a transparent carrier, each of the chips having an active surface with a plurality of electrode pads and an inactive surface opposite to the active surface, covering the active surfaces of the chips with a protection layer and fixing the inactive surfaces of the chips to the transparent carrier; encapsulating the chips with a first encapsulation layer while exposing the protection layer on the active surfaces of the chips; removing the protection layer to expose the active surfaces of the chips; forming a dielectric layer on the active surfaces of the chips and the first encapsulation layer, and forming a plurality of openings in the dielectric layer for exposing the electrode pads of the chips, respectively; and forming a wiring layer on the dielectric layer and electrically connecting the wiring layer to the electrode pads.

The method can further comprise forming a solder mask layer on the dielectric layer and the wiring layer and forming a plurality of openings in the solder mask layer for mounting of solder balls.

The method can further comprise separating the transparent carrier from the first encapsulation layer and the chips by laser and performing a singulation process to obtain a plurality of wafer level chip scale packages (WLCSPs). Alternatively, the step of separating the transparent carrier from the first encapsulation layer and the chips can be performed after the step of forming the dielectric layer or after the step of forming the wiring layer. Thereafter, a solder mask layer can be formed on the dielectric layer and the wiring layer and have a plurality of openings for mounting of solder balls.

The method can further comprise coating a second encapsulation layer made of such as polyimide on the surface of the transparent carrier, and fixing the inactive surfaces of the chips to the second encapsulation layer. The method can further comprise forming a built-up structure on the dielectric layer and the wiring layer through a redistribution layer (RDL) technique. According to the present method, the transparent carrier can be easily separated from the first encapsulation layer and the chips by laser and repetitively used so as to increase the process efficiency and reduce the fabrication cost.

Through the above-described fabrication method, the present invention further discloses a chip scale package, which comprises: a chip having an active surface with a plurality of electrode pads and an inactive surface opposite to the active surface; a first encapsulation layer encapsulating the chip and having a height greater than a thickness of the chip; a dielectric layer formed on the active surface of the chip and the first encapsulation layer and having a plurality of openings for exposing the electrode pads of the chip; a wiring layer formed on the dielectric layer and electrically connected to the electrode pads; and a second encapsulation layer formed on the inactive surface of the chip and the first encapsulation layer, wherein the second encapsulation layer is made of polyimide.

The package further comprises: a solder mask layer disposed on the dielectric layer and the wiring layer and having a plurality of openings for exposing a certain portion of the wiring layer; and solder balls implanted on the certain portion of the wiring layer.

Therefore, the present invention mainly involves forming a protection layer on the active surface of a chip and fixing the inactive surface of the chip to a transparent hard carrier, then performing a molding process and removing the protection layer, and subsequently performing an RDL process so as to avoid the conventional problems caused by directly attaching the active surface of the chip on an adhesive film in the prior art, such as film-softening caused by heat, encapsulant overflow, chip deviation and contamination that lead to poor electrical connection between the wiring layer formed in a subsequent RDL process and the chip electrode pads and even waste product as a result. Further, the transparent carrier employed in the invention can be separated by laser focusing on the interface between the transparent carrier and the first encapsulation layer and between the carrier and the chip, such that the transparent carrier can be repetitively used in the process, thereby reducing the fabrication cost. Furthermore, the present invention eliminates the use of an adhesive film as in the prior art and accordingly avoids warpage of the package structure, and also avoids the conventional problems of complicated processes, increased fabrication cost and adhesive residue caused by the additional use of a hard carrier for overcoming warpage in the prior art.

### BRIEF DESCRIPTION OF DRAWINGS

FIGS. 1A to 1C are cross-sectional views showing a fabrication method of a wafer level chip scale package according to U.S. Pat. No. 6,271,469;

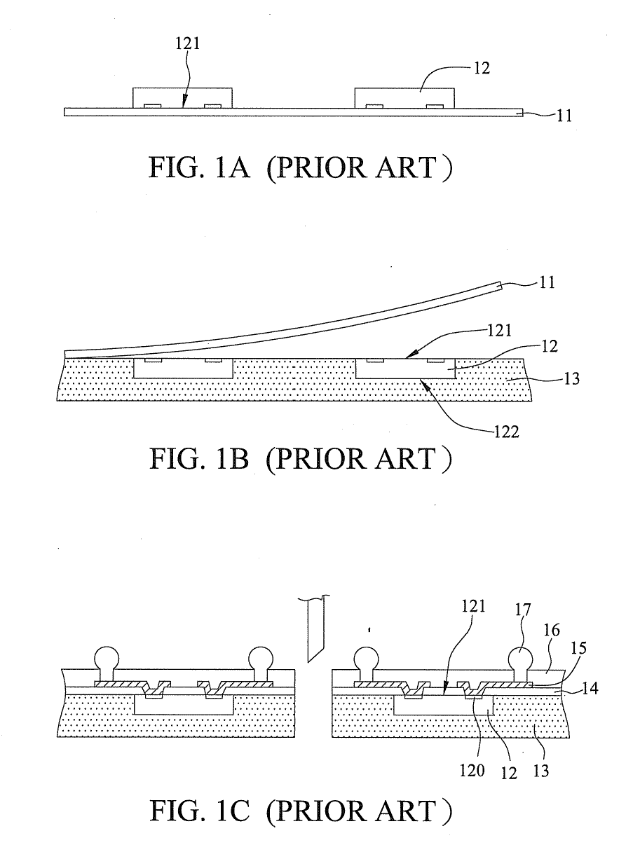

FIG. 2 is a cross-sectional view showing encapsulant overflow of the package according to U.S. Pat. No. 6,271,469;

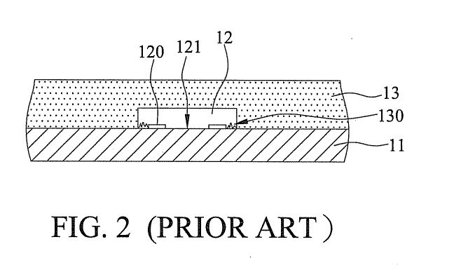

FIG. 3A is a cross-sectional view showing warpage of the package according to U.S. Pat. No. 6,271,469;

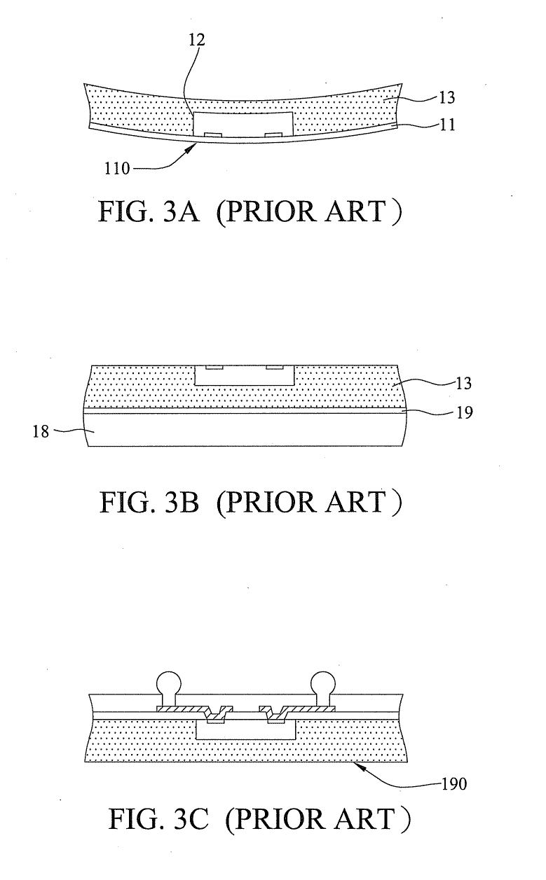

FIG. 3B is a cross-sectional view showing application of a hard carrier to the package according to U.S. Pat. No. 6,271,469;

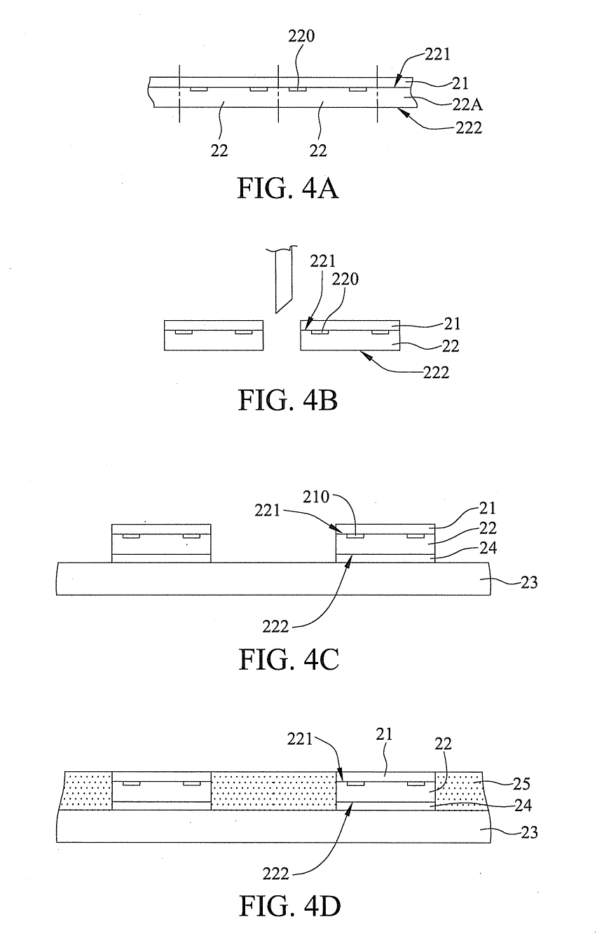

FIG. 3C is a cross-sectional view showing the problem of adhesive residue of the package according to U.S. Pat. No. 6,271,469;

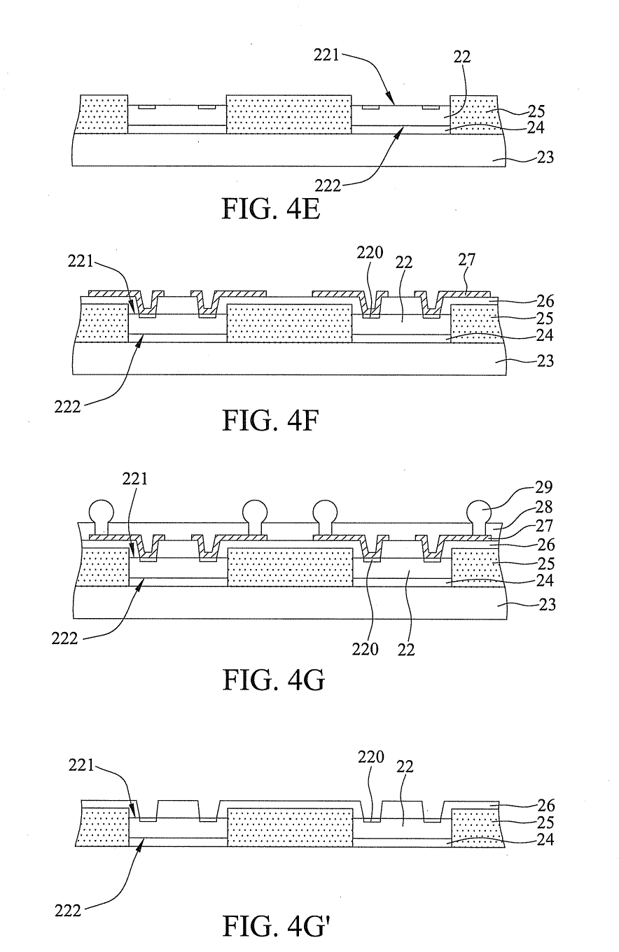

FIGS. 4A to 4H are cross-sectional views showing a chip scale package and a fabrication method thereof according to a first embodiment of the present invention;

FIGS. 5A to 5D are cross-sectional views showing a chip scale package and a fabrication method thereof according to a second embodiment of the present invention; and

FIG. 6 is a cross-sectional view showing a chip scale package and a fabrication method thereof according to a third embodiment of the present invention.

### DETAILED DESCRIPTION OF PREFERRED EMBODIMENTS

The following illustrative embodiments are provided to illustrate the disclosure of the present invention, these and other advantages and effects can be apparent to those in the art after reading this specification.

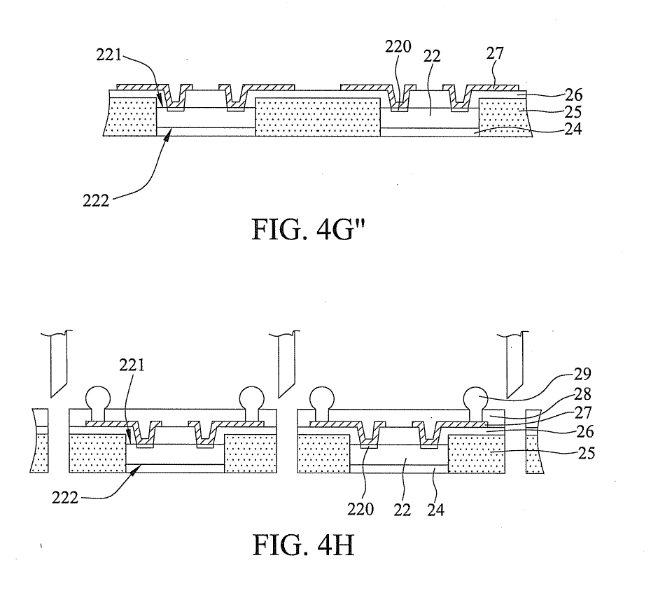

FIGS. 4A to 4H are cross-sectional views showing a chip scale package and a fabrication method thereof according to a first embodiment of the present invention.

Referring to FIGS. 4A and 4B, a wafer 22A having a plurality of chips 22 is provided, wherein the wafer 22A and the chips 22 each have an active surface 221 and an opposite inactive surface 222, and each of the chips 22 has a plurality of electrode pads 220 disposed on the active surface 221 thereof. Further, a protection layer 21 is formed on the active surface 221 of the wafer and has a thickness of about 3 to 20 μm. Then, the wafer 22A is cut into the plurality of chips 22 with the protection layer disposed on the active surface 221 thereof.

Referring to FIG. 4C, a transparent hard carrier 23 is provided, and the inactive surfaces 222 of the chips 22 are attached to the transparent hard carrier 23 through an adhesive 24 and fixed by curing.

Referring to FIG. 4D, a package molding process is performed to form a first encapsulation layer 25 encapsulating the chips 22 while exposing the protection layer 21 on the active surfaces 221 of the chips 22. The encapsulation layer 25 can be made such as an epoxy resin.

Referring to FIG. 4E, the protection layer is removed by using such as a chemical agent so as to expose the active surfaces 221 of the chips 22. As such, the first encapsulation layer 25 is higher than the active surfaces 221 of the chips 22.

Referring to FIG. 4F, a dielectric layer 26 is formed on the active surfaces 221 of the chips 22 and the first encapsulation layer 25, and a photolithography process or a laser process is performed to form a plurality of openings in the dielectric layer 26 for exposing the electrode pads 220 of the chips 22, respectively. Therein, the dielectric layer 26 functions as a seed layer that allows a subsequently formed wiring layer to be attached thereto.

Then, by using an RDL technique, a wiring layer 27 is formed on the dielectric layer 26 and electrically connected to the electrode pads 220 of the chips 22.

Referring to FIG. 4G a solder mask layer 28 is formed on the dielectric layer 26 and the wiring layer 27, and a plurality of openings is formed in the solder mask layer 28 to expose a certain portion of the wiring layer 27 such that solder balls 29 can be mounted thereon. Thereafter, the transparent hard carrier 23 is easily removed by laser focusing on the interface between the transparent hard carrier 23 and the first encapsulation layer 25 and between the transparent hard carrier 23 and the adhesive layer 24.

Alternatively, referring to FIGS. 4G′ and 4G″, the transparent hard carrier 23 can be removed after the step of forming the dielectric layer 26 or after the step of forming the wiring layer 27. Subsequently, the solder mask layer 28 can be formed on the dielectric layer 26 and the wiring layer 27 and have a plurality of openings for mounting of solder balls 29 after the step of removing the transparent hard carrier 23.

Referring to FIG. 4H, a singulation process is performed to obtain a plurality of wafer level chip scale packages (WLCSPs).

Therefore, the present invention mainly involves forming a protection layer on the active surface of a chip and fixing the inactive surface of the chip to a transparent hard carrier, then performing a molding process and removing the protection layer, and subsequently performing an RDL process to avoid the conventional problems caused by directly attaching the active surface of the chip on an adhesive film as in the prior art, such as film-softening caused by heat, encapsulant overflow, chip deviation and contamination that lead to poor electrical connection between the wiring layer in a subsequent RDL process and the chip electrode pads and even waste product as a result. Further, the transparent carrier employed in the invention can be separated by laser focusing on the interface between the carrier and the first encapsulation layer and between the carrier and the chip so as to be repetitively used in the process, thereby reducing the fabrication cost. Furthermore, the present invention eliminates the use of an adhesive film as in the prior art and accordingly avoids warpage of the package, and also avoids the conventional problems of complicated processes, increased fabrication cost and adhesive residue caused by additional use of a hard carrier for overcoming warpage of the package structure in the prior art.

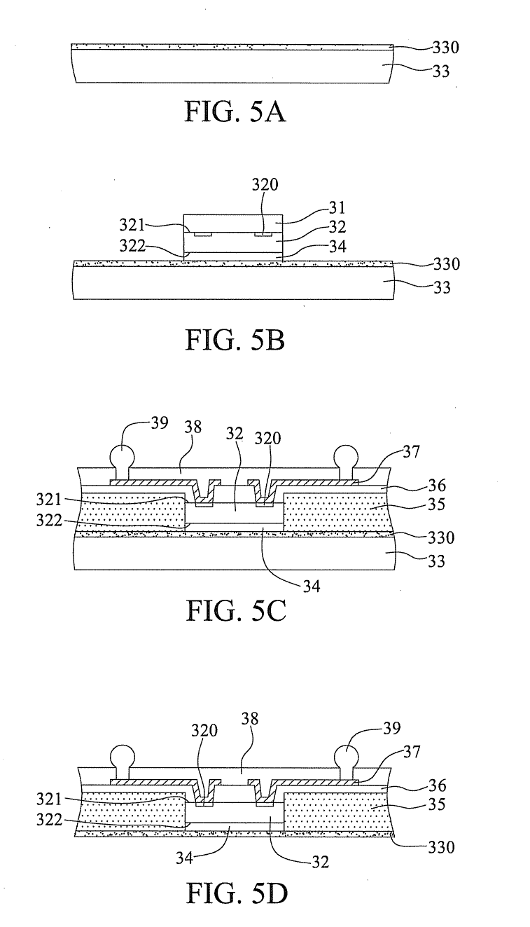

FIGS. 5A to 5D are cross-sectional views showing a chip scale package and a fabrication method thereof according to a second embodiment of the present invention. The present embodiment is similar to the first embodiment. A main difference of the present embodiment from the first embodiment is that a second encapsulation layer is formed on the inactive surfaces of the chips for protecting the chips.

Referring to FIG. 5A, a transparent hard carrier 33 is provided and a second encapsulation layer 330 made of such as polyimide is formed on the transparent hard carrier 33 by, for example, coating.

Referring to FIG. 5B, a plurality of chips 32 with a protection layer 31 disposed on the active surfaces thereof is provided and the inactive surfaces of the chips 32 are attached to the second encapsulation layer 330 through an adhesive 34.

Referring to FIG. 5C, a package molding process is performed to form a first encapsulation layer 35 encapsulating the chips 32 while exposing the protection layer 31 on the active surfaces 321 of the chips 32, wherein the encapsulation layer 35 is made of such as an epoxy resin. Then, the protection layer 31 is removed to expose the active surfaces 321 of the chips 32 such that a dielectric layer 36 is formed on the active surfaces 321 of the chips 32 and the first encapsulation layer 35 and a wiring layer 37 is formed on the dielectric layer 36.

Thereafter, a solder mask layer 38 with a plurality of openings is formed on the dielectric layer 36 and the wiring layer 37, and solder balls 39 are mounted in the openings of the solder mask layer 38.

Referring to FIG. 5D, the transparent hard carrier 33 is removed in the same manner as the first embodiment and then a singulation process is performed.

Therein, the second encapsulation layer 330 disposed on the inactive surfaces 322 of the chips 32 provides protection to the chip.

Through the above-described method, the present invention further discloses a chip scale package, which comprises: a chip 32 having an active surface 321 with a plurality of electrode pads 320 and an inactive surface 322 opposite to the active surface 321; a first encapsulation layer 35 encapsulating the chip 32 and having a height greater than that of the chip 32; a dielectric layer 36 disposed on the active surface 321 of the chip 32 and the first encapsulation layer 35 and having a plurality of openings for exposing the electrode pads 320 of the chip 32; a wiring layer 37 disposed on the dielectric layer 36 and electrically connected to the electrode pads 320; and a second encapsulation layer 330 disposed on the inactive surface 322 of the chip 32 and the first encapsulation layer 35, wherein the second encapsulation layer is made of polyimide.

The chip scale package can further comprise a solder mask layer 38 disposed on the dielectric layer 36 and the wring layer 37 and having a plurality of openings for exposing a certain portion of the wiring layer 37; and solder balls 39 disposed on the certain portion of the wiring layer 37.

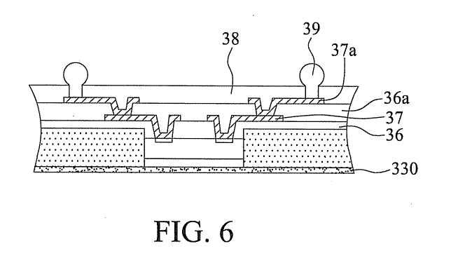

FIG. 6 is cross-sectional view showing a chip scale package and a fabrication method thereof according to a third embodiment of the present invention. Referring to the drawing, the present embodiment is similar to the second embodiment. The difference of the present embodiment from the second embodiment is that a built-up structure is further formed on the dielectric layer and the wiring layer by using the RDL technique. For example, a second dielectric layer 36a and a second wiring layer 37a are further formed on the dielectric layer 36 and the wiring layer 37, and the second wiring layer 37a is electrically connected to the first wiring layer 37. Thereafter, a solder mask layer 38 is formed on the second wiring layer 37a and a plurality of openings is formed in the solder mask layer 38 for exposing a certain portion of the second wiring layer 37a. Subsequently, solder balls 39 are mounted on the certain portion of the second wiring layer 37a so as to function as I/O terminals of the package for electrically connecting to an external device. By increasing the number of built-up layers, the flexibility of wiring layout of the package can be improved.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A fabrication method of a chip scale package, comprising the steps of:
providing a plurality of chips and a transparent carrier, each of the chips having an active surface with a plurality of electrode pads and an inactive surface opposite to the active surface, covering the active surfaces of the chips with a protection layer and fixing the inactive surfaces of the chips to the transparent carrier;
encapsulating the chips with a first encapsulation layer while exposing the protection layer on the active surfaces of the chips;
removing the protection layer to expose the active surfaces of the chips;
forming a dielectric layer on the active surfaces of the chips and the first encapsulation layer, and forming a plurality of openings in the dielectric layer for exposing the electrode pads of the chips, respectively; and
forming a wiring layer on the dielectric layer and electrically connecting the wiring layer to the electrode pads.

2. The method of claim 1, further comprising forming a solder mask layer on the dielectric layer and the wiring layer and forming a plurality of openings in the solder mask layer for mounting of solder balls.

3. The method of claim 2, further comprising separating the transparent carrier from the first encapsulation layer and the chips by laser.

4. The method of claim 1, further comprising separating the transparent carrier from the first encapsulation layer and the chips by laser after the step of forming the dielectric layer.

5. The method of claim 4, further comprising forming a solder mask layer on the dielectric layer and the wiring layer and forming a plurality of openings in the solder mask layer for mounting of solder balls.

6. The method of claim 1, further comprising separating the transparent carrier from the first encapsulation layer and the chips by laser after the step of forming the wiring layer.

7. The method of claim 6, further comprising forming a solder mask layer on the dielectric layer and the wiring layer and forming a plurality of openings in the solder mask layer for mounting of solder balls

8. The method of claim 1, further comprising forming a second encapsulation layer on the transparent carrier so as for the inactive surfaces of the chips to be fixed to the second encapsulation layer.

9. The method of claim 8, wherein the second encapsulation layer is coated on the transparent carrier.

10. The method of claim 8, wherein the second encapsulation layer is made of polyimide.

11. The method of claim 1, wherein a height of the first encapsulation layer is greater than a thickness of each of the chips.

12. The method of claim 1, further comprising forming a built-up structure on the dielectric layer and the wiring layer through a redistribution layer (RDL) technique.

13. The method of claim 1, wherein the plurality of chips are formed by: providing a wafer having an active surface and an opposite inactive surface; forming a protection layer on the active surface of the wafer; cutting the wafer into the plurality of chips with the protection layer formed on the active surfaces thereof.

14. A chip scale package, comprising:
a chip having an active surface with a plurality of electrode pads and an inactive surface opposite to the active surface;
a first encapsulation layer encapsulating the chip and having a height greater than a thickness of the chip;
a dielectric layer formed on the active surface of the chip and the first encapsulation layer and having a plurality of openings for exposing the electrode pads of the chip;
a wiring layer formed on the dielectric layer and electrically connected to the electrode pads; and
a second encapsulation layer formed on the inactive surface of the chip and the first encapsulation layer, wherein the second encapsulation layer is made of polyimide.

15. The package of claim 14, further comprising a solder mask layer formed on the dielectric layer and the wiring layer and having a plurality of openings for exposing a certain portion of the wiring layer; and solder balls implanted on the certain portion of the wiring layer.

16. The package of claim 14, further comprising a built-up structure disposed on the dielectric layer and the wiring layer.
